(19) United States
(12) Patent Application Publication
(10) Pub. No.: US 2025/0374752 A1
(43) Pub. Date: Dec. 4, 2025

(54) OLED STRUCTURE WITH A U-SHAPED ANODE AND FABRICATING METHOD OF THE SAME

(71) Applicant: UNITED MICROELECTRONICS CORP., Hsin-Chu City (TW)

(72) Inventor: ZHIBIAO ZHOU, Singapore (SG)

(73) Assignee: UNITED MICROELECTRONICS CORP., Hsin-Chu City (TW)

(21) Appl. No.: 18/751,356

(22) Filed: Jun. 24, 2024

(30) Foreign Application Priority Data
Jun. 4, 2024 (TW) 113120597

(51) Int. Cl. H10K 50/813; H10K 59/131; H10K 59/80; H10K 59/88; H10K 71/00; H10K 71/60

(52) U.S. Cl. CPC H10K 50/813; H10K 59/131; H10K 59/873; H10K 59/88; H10K 71/60; H10K 71/621

(57) ABSTRACT

An OLED structure with a U-shaped anode includes a substrate. The substrate is divided into a pixel area and an external circuit area. Numerous OLEDs are disposed in the pixel area on the substrate. Each OLED includes a first anode, a second anode, a light-emitting layer and a cathode stacked in sequence from bottom to top. The material of the first anode is different from the material of the second anode. The second anode has a U-shape profile, and the opening of U-shape profile faces the light-emitting layer. A first metal layer is disposed in the external circuit area on the substrate. The top surface of the first metal layer is aligned with the top surface of the first anode.

### BACKGROUND OF THE INVENTION

### 1. Field of the Invention

The invention relates to an organic light emitting diode (OLED) structure and a fabricating method thereof, and more particularly relates to an OLED structure with a U-shaped anode and a fabricating method thereof.

### 2. Description of the Prior Art

As demands for electronic products gradually increases and lighting application technology improve, OLED technology develops rapidly. Display devices or lighting equipment with OLEDs not only have the advantage of self-luminescence, but the thickness and volume of the panel becomes thinner and smaller. Because OLEDs have short response time and high luminous efficiency, higher pixels are easier to be achieved by using OLEDs as light source. Therefore, OLEDs are suitable for smart wearable devices.

The high-tech trend brings high convenience and fun. Smart wearable devices become popular. Smart glasses are one of the smart wearable devices developed by many companies. Smart glasses are divided into augmented reality (AR) smart glasses and virtual reality (VR) smart glasses. AR smart glasses and VR smart glasses are important commercial products applied in AR and VR technology. OLEDs serve as light sources for AR and VR. Therefore, how to increase the color saturation and color uniformity of OLEDs has become a major goal today.

### SUMMARY OF THE INVENTION

In view of above, the present invention provides a fabricating method which can keep the surface of the second anode flat to provide OLEDs with uniform color.

According to a preferred embodiment of the present invention, an OLED structure with a U-shaped anode includes a substrate, wherein the substrate includes a pixel area and an external circuit area. Numerous OLEDs are disposed in the pixel area on the substrate, wherein each of the OLEDs includes a first anode, a second anode, a light-emitting layer and a cathode stacked in sequence from bottom to top, material of the first anode is different from material of the second anode, and the second anode has a U-shape profile, and an opening of the U-shape profile faces the light-emitting layer. A first metal layer is disposed in the external circuit area on the substrate, wherein a top surface of the first metal layer is aligned with a top surface of the first anode.

According to another preferred embodiment of the present invention, a fabricating method of an OLED structure with a U-shaped anode includes providing a substrate including a pixel area and an external circuit area. Next, a first metal material layer is formed to cover the substrate. Later, the first metal material layer is patterned to form numerous first anodes in the pixel area, numerous dummy metal blocks between the pixel area and the external circuit area, and a first metal layer in the external circuit area. Next, a dielectric layer is formed to cover numerous first anodes, numerous dummy metal blocks and the first metal layer. Subsequently, the dielectric layer is patterned to form numerous openings in the dielectric layer, wherein each of the first anodes and the first metal layer are respectively exposed through one of the openings, and the dummy metal blocks are not exposed from the dielectric layer. Later, a second metal material layer is formed to cover the dielectric layer and cover the openings. Finally, the second metal material layer outside of the openings is removed to segment the remaining second metal material layer into numerous second anodes and a second metal layer, wherein each of the second anodes contacts one of the first anodes, and the second metal layer contacts the first metal layer.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 to FIG. 8 depict a fabricating method of a U-shaped anode of an OLED according to a preferred embodiment of the present invention, wherein:

FIG. 1 shows a substrate with a pixel area and an external circuit area;

FIG. 2 depicts a fabricating stage in continuous of FIG. 1;

FIG. 3 shows a top view of FIG. 2;

FIG. 4 depicts a fabricating stage in continuous of FIG. 2;

FIG. 5 depicts a fabricating stage in continuous of FIG. 4;

FIG. 6 depicts a fabricating stage in continuous of FIG. 5;

FIG. 7 depicts a fabricating stage in continuous of FIG. 6; and

FIG. 8 depicts a fabricating stage in continuous of FIG. 7.

FIG. 9 illustrates a fabricating method of an OLED structure with a U-shaped anode according to a preferred embodiment of the present invention.

FIG. 10 depicts a fabricating method of a U-shaped anode of an OLED according to another preferred embodiment of the present invention.

### DETAILED DESCRIPTION

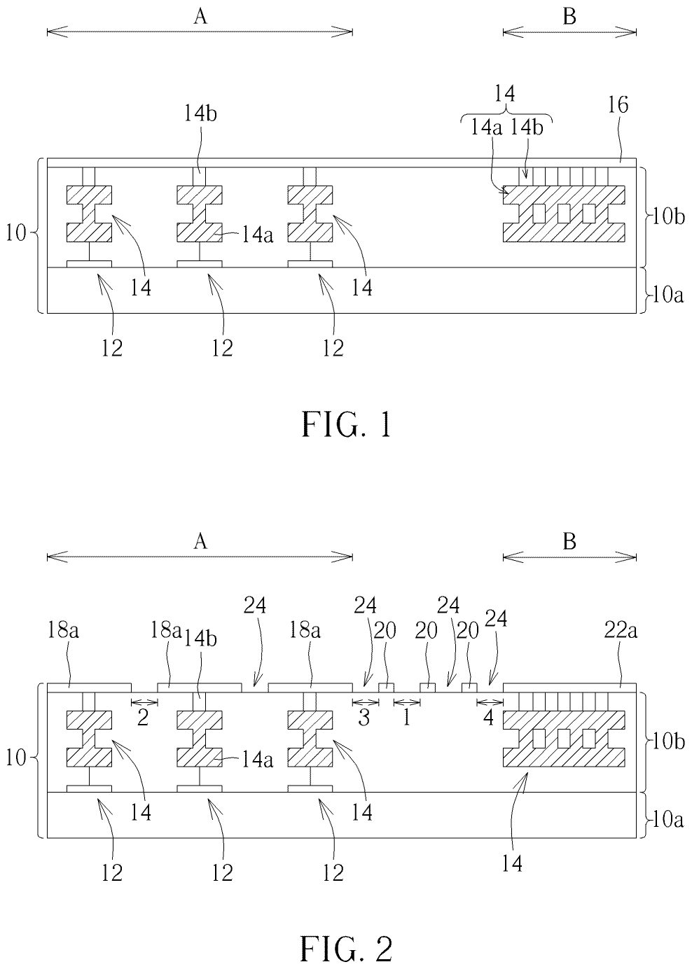

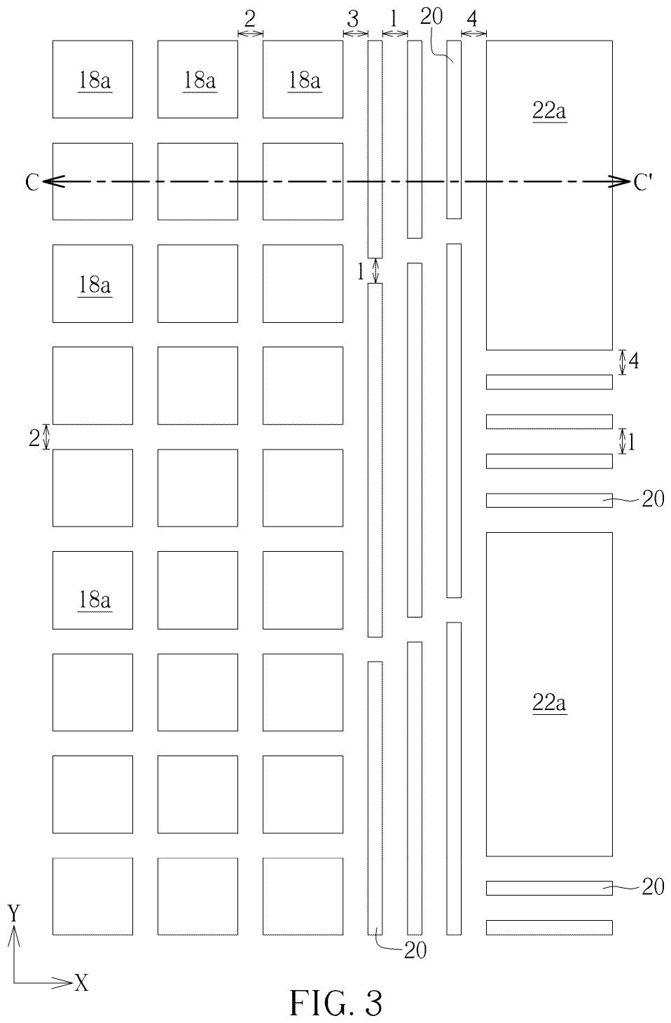

FIG. 1 to FIG. 8 depict a fabricating method of a U-shaped anode of an OLED according to a preferred embodiment of the present invention, wherein FIG. 2 is a schematic sectional view taken along a line CC′ in FIG. 3. FIG. 9 illustrates a fabricating method of an OLED structure with a U-shaped anode according to a preferred embodiment of the present invention.

As shown in FIG. 1, a substrate 10 is provided. The substrate 10 is divided into a pixel area A and an external circuit area B. The substrate 10 includes a semiconductor substrate 10a and a dielectric layer 10b. The semiconductor substrate 10a may be a silicon substrate, a germanium substrate, a gallium arsenide substrate, a silicon germanium substrate, an indium phosphide substrate, a gallium nitride substrate, a silicon carbide substrate or a silicon-on-insulator (SOI) substrate. The dielectric layer 10b covers the semiconductor substrate 10a. The dielectric layer 10b may include one or more layers of insulating materials, such as silicon oxide, silicon nitride, silicon carbon nitride (SiCN), silicon oxynitride, or silicon carbon oxynitride (SiCON). Numerous of driving transistors 12, such as thin film transistors, are disposed on the semiconductor substrate 10a in the pixel area A. Numerous sets of metal interconnections 14 are respectively disposed in the pixel area A and in the dielectric layer 10b within the external circuit area B. The metal interconnections 14 may be copper conductive lines 14a and tungsten conductive lines 14b formed by a back end of line process. A source or a drain of each of the driving transistor 12 is electrically connected to the metal interconnections 14 in the pixel area A. In this stage, the topmost surface of the metal interconnections 14 in the pixel area A and the topmost surface of the metal interconnections 14 in the external circuit area B are coplanar. Each driving transistor 12 is used to control the brightness and switch of the corresponding OLED. The metal interconnections 14 in the external circuit area B is electrically connected to the driving transistors 12 to make external signals to be transmitted to each OLED through the external circuit area B.

Then, a first metal material layer 16 is formed to cover the substrate 10. The first metal material layer 16 is preferably aluminum. The method of forming aluminum include physical vapor deposition, chemical vapor deposition or hot aluminum deposition process. The hot aluminum deposition process includes depositing aluminum at a high temperature by heating the substrate 10. The operating temperature of the deposition processes is preferably between 450° C. to 500° C. to increase roughness of the surface of aluminum. Rough surface of aluminum is beneficial for OLED to reflect light.

As shown in FIG. 2 and FIG. 3, the first metal material layer 16 is patterned to form numerous first anodes 18a in the pixel area A, numerous dummy metal blocks 20 between the pixel area A and the external circuit area B, and at least one first metal layer 22a in the external circuit area B. The dummy metal blocks 20 can not only be disposed between the first anode 18a and the first metal layer 22a, but also can be disposed between different first metal layers 22a. Along a first direction X, a first space 1 is between each of the dummy metal blocks 20. A second space 2 is between each of the first anodes 18a. The first space 1 and the second space 2 are the same. Moreover, along the first direction X, a third space 3 is disposed between the first anode 18a which is closest to the dummy metal blocks 20 and the dummy metal block 20 which is closest to the first anode 18a. A fourth space 4 is disposed between the first metal layer 22a and the dummy metal block 20 which is closest to the first metal layer 22a. The third space 3 is the same as the first space 1, and the fourth space 4 is the same as the first space 1. In other words, the first space 1, the second space 2, the third space 3 and the fourth space 4 are all the same. In addition, according to another preferred embodiment of the present invention, a second direction Y is perpendicular to the first direction X. Along the second direction Y, The first space 1 is also between the dummy metal blocks 20. The second space 2 is also between the first anodes 18a. Along the second direction Y, a fourth space 4 is also disposed between the first metal layer 22a and the dummy metal block 20 which is closest to the first metal layer 22a. Numerous trenches 24 can be defined by combing the first space 1, the second space 2, the third space 3, the fourth space 4 to the sidewall of the first anode 18a, the sidewall of the dummy metal block 20 or the sidewall of the first metal layer 22a. The aspect ratio of the trench 24 can be adjusted according to different products. For example, the aspect ratio of the trench 24 can be less than 0.5 or greater than 2.

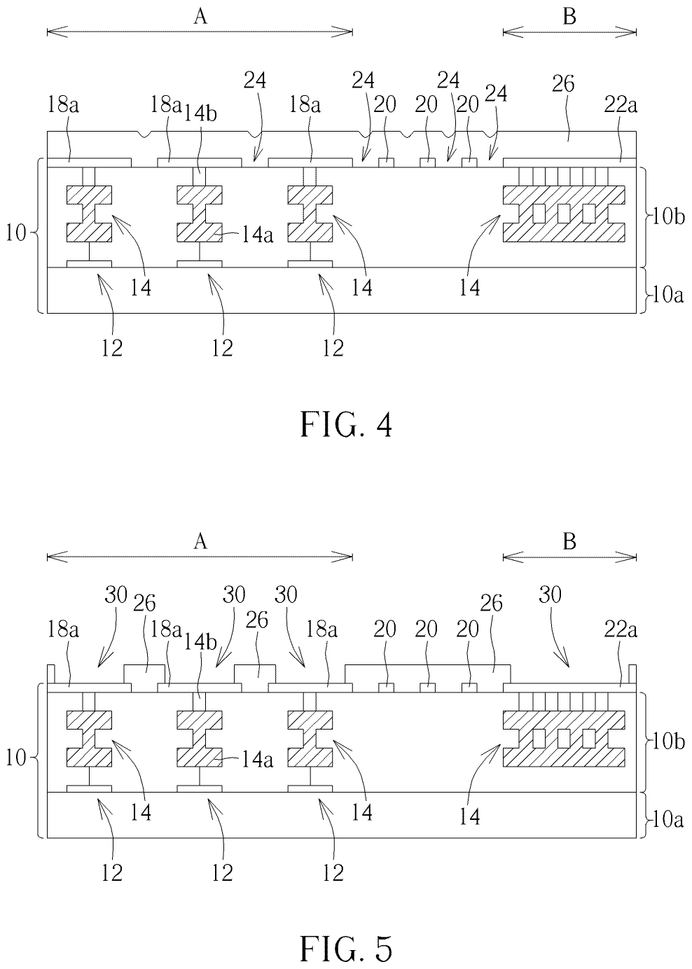

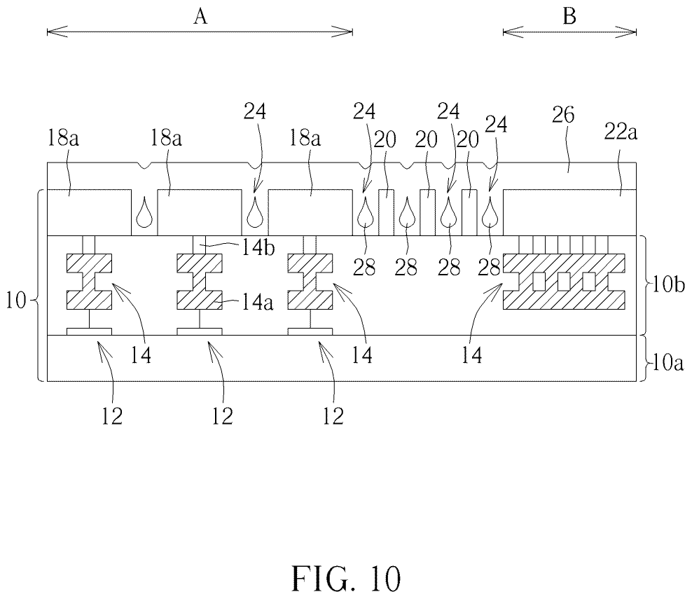

As shown in FIG. 4, a dielectric layer 26 is formed to cover all the first anodes 18a, all the dummy metal blocks 20 and the first metal layer 22a. The dummy metal blocks 20 allows the gap between the first anode 18a and the first metal layer 22a to be divided into several even spaces, therefore, the top surface of the dielectric layer 26 will not be excessively recessed because of the large space in a specific area. Excessive recess will result in poor coverage of the dielectric layer 26. Furthermore, different aspect ratios of the trench 24 will affect whether the dielectric layer 26 can fill up the trench 24. For example, as shown in FIG. 4, when the aspect ratio of the trench 24 is less than 0.5, the dielectric layer 26 fills up the trench 24. As shown in FIG. 10, if the aspect ratio of the trench is greater than 2, the dielectric layer 26 cannot fill up the trench 24. An air gap 28 is therefore formed within the dielectric layer 26 in the trench 24.

FIG. 5 is shows steps in continuous of the steps in FIG. 4. As shown in FIG. 5, the dielectric layer 26 is patterned to form numerous openings 30 in dielectric layer 26. Each of the first anodes 18a and the first metal layer 22a are respectively exposed through one of openings 30. But all dummy metal blocks 20 are not exposed from the dielectric layer 26. Steps of patterning the dielectric layer 26 include exposure, development and etching processes. After the dielectric layer 26 is patterned, an acid cleaning process is performed. The acid cleaning process includes cleaning the first anodes 18a to make the surface of the first anodes 18a rougher. The acid cleaning process can use etching solutions which etches aluminum such as phosphoric acid or hydrochloric acid.

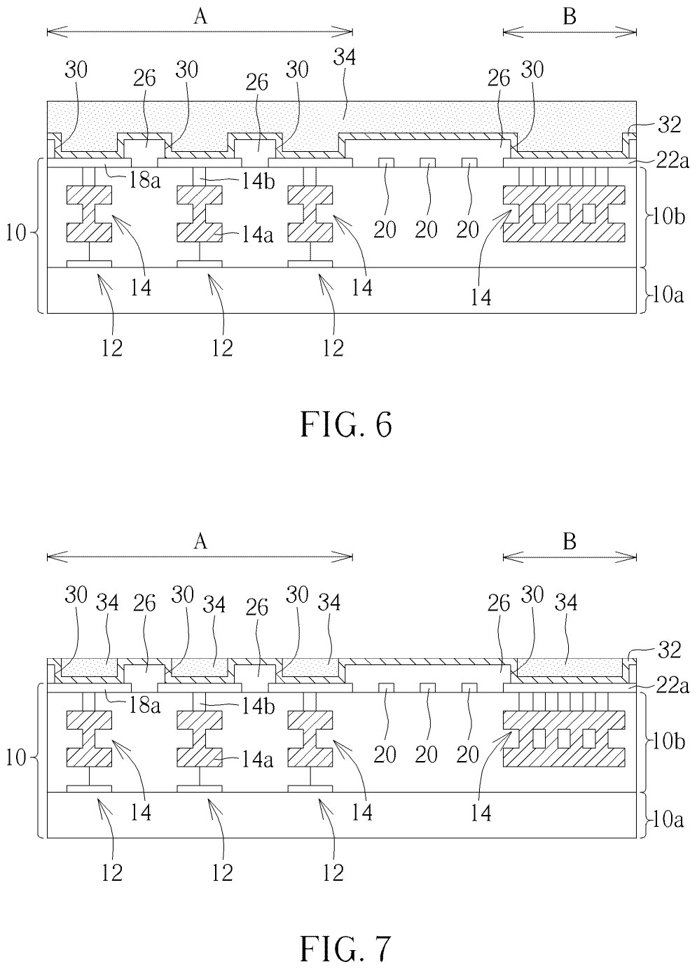

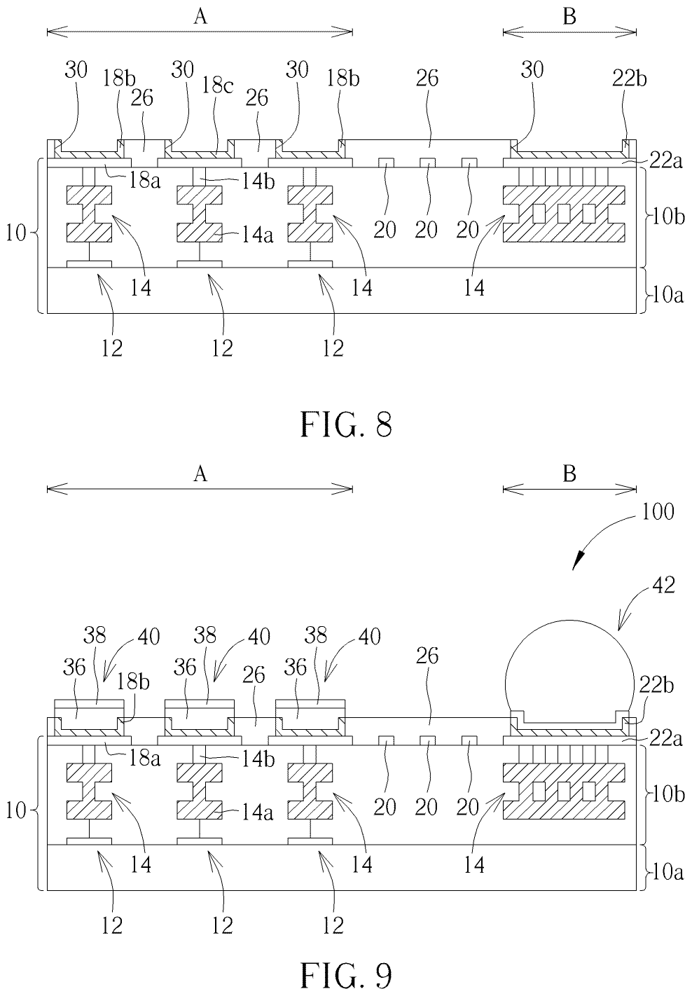

As shown in FIG. 6, a second metal material layer 32 is formed to cover the dielectric layer 26 and all openings 30. Then, a photoresist 34 is formed to cover the second metal material layer 32 and fill the openings 30. At this time, the top surface of the photoresist 34 is higher than the top surface of the second metal material layer 32. As shown in FIG. 7, the photoresist 34 is etched to make the top surface of the photoresist 34 and the top surface of the second metal material layer 32 are aligned by taking the second metal material layer 32 as a first etching stop layer. As shown in FIG. 8, the second metal material layer 32 is etched until the second metal material layer 32 outside of the openings 30 is removed by taking the dielectric layer 26 as a second etching stop layer. Then, the photoresist 34 is completely removed. Now, the remaining second metal material layer 30 is segmented to form numerous second anodes 18b and a second metal layer 22b. Each of the second anodes 18b is in contact with one of the first anodes 18a. The second metal layer 22b contacts the first metal layer 22a. The U-shaped second anode 18b of the present invention is completed. When viewing from the sectional view, each of the second anodes 18b is U-shaped. Since the U-shaped bottom 18c is not exposed during the forming process of the second anode 18b, the U-shaped bottom 18c will not be damaged by the etchant. In this way, the U-shaped bottoms 18c of all the second anodes 18b have substantially the same thickness to provide the same electric field. Therefore, the emission rate of OLEDs can be in consistent.

As shown in FIG. 9, an OLED structure 100 with a U-shaped anode includes a substrate 10. The substrate 10 includes a pixel area A and an external circuit area B. Numerous OLEDs 40 are disposed in the pixel area A on the substrate 10. Each of the plurality of OLEDs 40 includes a first anode 18a, a second anode 18b, a light-emitting layer 36 and a cathode 38 stacked in sequence from bottom to top. Material of the first anode 18a is different from material of the second anode 18b. When viewing from a sectional view, the second anode 18b has a U-shape profile, and an opening of U-shape profile faces the light-emitting layer 36. A first metal layer 22a is disposed in the external circuit area B on the substrate 10. A top surface of the first metal layer 22a is aligned with a top surface of the first anode 18a. Material of the first metal layer 22a is the same as material of the first anode 18a. A second metal layer 22b is disposed on the first metal layer 22a. When viewing from a sectional view, the second metal layer 22b is U-shaped. Material of the second metal layer 22a is the same as material of the second anode 18b. Material of the second metal layer 22b and material of the second anode 18b respectively include titanium, titanium nitride, tantalum, tantalum nitride, tungsten, nickel, molybdenum, gold, palladium, aluminum, silver, calcium, indium, lithium, magnesium or indium tin oxide (ITO). Material of the cathode 38 includes a transparent conductive material, such as indium tin oxide (ITO), fluorine-doped indium oxide (FTO) or indium zinc oxide (IZO), etc. The light-emitting layer 36 can include fluorescent material or phosphorescent material.

Numerous dummy metal blocks 20 are disposed on the substrate 10 between the pixel area A and the external circuit area B. Material of the first anode 18a, material of the first metal layer 22a, and material of the dummy metal blocks 20 are preferably the same. For example, material of the first anode 18a, material of the first metal layer 22a, and material of the dummy metal blocks 20 may be aluminum. In addition, all dummy metal blocks 20 are not electrically connected to any conductive elements. Furthermore, a dielectric layer 26 covers all of the dummy metal blocks 20, part of the first anode 18a and part of the first metal layer 22a. The dielectric layer 26 may be silicon oxide, silicon nitride, silicon carbon nitride (SiCN), silicon oxynitride, or silicon carbon oxynitride (SiCON). A bumping 42 electrically contacts and connects the second metal layer 22b. The Bumping 42 can be replaced by a wire bonding. Bumping 42 includes conductive materials such as gold or tin-lead alloy.

Moreover, the light-emitting layer 36 emits light toward the cathode 38. That is, the OLED structure 100 with a U-shaped anode of the present invention is a top emission structure. Because the first anode 18a has a rough surface, the light emitted from the light-emitting layer 36 toward the first anode 18a can be reflected or refracted by the rough surface to become proceeds toward the cathode 38.

The present invention uses photoresist to form a U-shaped second anode by a self-aligned manner. In this way, the U-shaped bottom of the second anode will not be damaged by etchant and can maintain the original thickness. Therefore, the thickness of the U-shaped bottom of each second anode is the same, so the emission rate of every OLED can be in consistent. In addition, the dummy metal blocks help the top surface of the dielectric layer covering the first anode and the first metal layer to be similar in different areas. In this way, the excessive recess of the dielectric layer can be avoided.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. An organic light-emitting diode (OLED) structure with a U-shaped anode, comprising:
a substrate, wherein the substrate comprises a pixel area and an external circuit area;
a plurality of OLEDs disposed in the pixel area on the substrate, wherein each of the plurality of OLEDs comprises a first anode, a second anode, a light-emitting layer and a cathode stacked in sequence from bottom to top, material of the first anode is different from material of the second anode, and the second anode has a U-shape profile, and an opening of the U-shape profile faces the light-emitting layer; and
a first metal layer disposed in the external circuit area on the substrate, wherein a top surface of the first metal layer is aligned with a top surface of the first anode.

2. The OLED structure with a U-shaped anode of claim 1, further comprising a second metal layer disposed on the first metal layer, and wherein the second metal layer is U-shaped.

3. The OLED structure with a U-shaped anode of claim 2, wherein material of the second metal layer is the same as material of the second anode.

4. The OLED structure with a U-shaped anode of claim 2, wherein material of the second metal layer and material of the second anode respectively comprise titanium, titanium nitride, tantalum, tantalum nitride, tungsten, nickel, molybdenum, gold, palladium, aluminum, silver, calcium, indium, lithium, magnesium or indium tin oxide (ITO).

5. The OLED structure with a U-shaped anode of claim 1, wherein material of the first metal layer is the same as material of the first anode.

6. The OLED structure with a U-shaped anode of claim 1, further comprising a plurality of dummy metal blocks disposed on the substrate between the pixel area and the external circuit area, and wherein a first space is disposed between each of the plurality of dummy metal blocks, and a second space is disposed between each first anode of each of the plurality of OLEDs, and the first space and the second space are the same.

7. The OLED structure with a U-shaped anode of claim 6, wherein a third space is disposed between the first anode which is closest to the dummy metal blocks and the dummy metal block which is closest to the plurality of OLEDs, a fourth space is disposed between the first metal layer and the dummy metal block which is closest to the first metal layer, the third space is the same as the first space, and the fourth space is the same as the first space.

8. The OLED structure with a U-shaped anode of claim 6, wherein material of the first anode, material of the first metal layer, and material of the plurality of dummy metal blocks comprise aluminum.

9. The OLED structure with a U-shaped anode of claim 6, wherein the plurality of dummy metal blocks are not electrically connected to any conductive element.

10. The OLED structure with a U-shaped anode of claim 6, further comprising a dielectric layer covering the plurality of dummy metal blocks, part of the first anode and part of the first metal layer.

11. The OLED structure with a U-shaped anode of claim 1, further comprising a bumping or a wire bonding to electrically connect the second metal layer.

12. The OLED structure with a U-shaped anode of claim 1, wherein the light-emitting layer emits light toward the cathode.

13. A fabricating method of an organic light-emitting diode (OLED) structure with a U-shaped anode, comprising:
providing a substrate comprising a pixel area and an external circuit area;
forming a first metal material layer covering the substrate;
patterning the first metal material layer to form a plurality of first anodes in the pixel area, a plurality of dummy metal blocks between the pixel area and the external circuit area, and a first metal layer in the external circuit area;
forming a dielectric layer covering the plurality of first anodes, the plurality of dummy metal blocks and the first metal layer;
patterning the dielectric layer to form a plurality of openings in the dielectric layer, wherein each of the plurality of first anodes and the first metal layer are respectively exposed through one of the plurality of openings, and the plurality of dummy metal blocks are not exposed from the dielectric layer;
forming a second metal material layer covering the dielectric layer and covering the plurality of openings; and
removing the second metal material layer outside of the plurality of openings to segment the second metal material layer which remains into a plurality of second anodes and a second metal layer, wherein each of the plurality of second anodes contacts one of the plurality of first anodes, and the second metal layer contacts the first metal layer.

14. The fabricating method of an OLED structure with a U-shaped anode of claim 13, further comprising:
forming a light-emitting layer and a cathode sequentially to cover one of the plurality of second anodes; and
forming a bumping to electrically connect the second metal layer.

15. The fabricating method of an OLED structure with a U-shaped anode of claim 13, wherein each of the plurality of second anodes is U-shaped.

16. The fabricating method of an OLED structure with a U-shaped anode of claim 13, wherein the second metal layer is U-shaped.

17. The fabricating method of an OLED structure with a U-shaped anode of claim 13, wherein steps of removing the second metal material layer outside of the plurality of openings comprise:
forming a photoresist to cover the second metal material layer;
etching the photoresist until a top surface of the photoresist is aligned with a top surface of the second metal material layer by using the second metal material layer as a first etching stop layer;
etching the second metal material layer to remove the second metal material layer outside of the plurality of openings by using the dielectric layer as a second etching stop layer; and
entirely removing the photoresist.

18. The fabricating method of an OLED structure with a U-shaped anode of claim 13, wherein a first space is disposed between each of the plurality of dummy metal blocks, and a second space is disposed between each of the plurality of first anodes, and the first space and the second space are the same.

19. The fabricating method of an OLED structure with a U-shaped anode of claim 18, wherein a third space is disposed between the first anode which is closest to the dummy metal blocks and the dummy metal block which is closest to the plurality of OLEDs, a fourth space is disposed between the first metal layer and the dummy metal block which is closest to the first metal layer, the third space is the same as the first space, and the fourth space is the same as the first space.

20. The fabricating method of an OLED structure with a U-shaped anode of claim 13, wherein material of the plurality of first anodes and material of the plurality of second anodes are different.
